(19) United States
(12) Patent Application Publication
(10) Pub. No.: US 2025/0267956 A1
(43) Pub. Date: Aug. 21, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Eitaro MIYAKE, Tachikawa Tokyo (JP)

(73) Assignees: KABUSHIKI KAISHA TOSHIBA, Tokyo (JP); Toshiba Electronic Devices & Storage Corporation, Tokyo (JP)

(21) Appl. No.: 19/186,754

(22) Filed: Apr. 23, 2025

Related U.S. Application Data
(63) Continuation of application No. PCT/JP2024/007147, filed on Feb. 27, 2024.

(30) Foreign Application Priority Data
Jul. 31, 2023 (JP) 2023-124512

(51) Int. Cl. H10D 89/60; H10D 12/00; H10D 84/80

(52) U.S. Cl. CPC H10D 89/921; H10D 12/411; H10D 84/80

(57) ABSTRACT

First and second transistors are on a substrate. A first end of the first transistor and a second end of the second transistor are coupled to each other. A first terminal includes a first portion contacting a first conductor coupled to a third end of the first transistor, a second portion connected to the first portion, and a third portion connected to the second portion. A complex includes a second terminal and a first insulator partially covering the second terminal. The second terminal includes a fourth portion, a fifth portion, and a sixth portion. The fourth portion contacts a second conductor coupled to a fourth end of the second transistor. The fifth portion is connected to the fourth portion and aligned with the second portion of the first terminal. The sixth portion is connected to the fifth portion. The first insulator covers the fifth portion.

### CROSS-REFERENCE TO RELATED APPLICATIONS

This application is a Continuation Application of PCT Application No. PCT/JP2024/007147, filed Feb. 27, 2024 and based upon and claiming the benefit of priority from Japanese Patent Application No. 2023-124512, filed Jul. 31, 2023, the entire contents of all of which are incorporated herein by reference.

### FIELD

Embodiments described herein relate generally to a semiconductor device.

### BACKGROUND

A semiconductor device includes a power module that deals with a high voltage. The power module can be formed as one package including a plurality of power semiconductor elements.

### BRIEF DESCRIPTION OF THE DRAWINGS

FIG. 1 is a perspective view showing an example of the outer appearance of a semiconductor device according to a first embodiment.

FIG. 2 is a circuit diagram showing an example of an electric circuit of the semiconductor device according to the first embodiment.

FIG. 3 schematically shows an example of the internal structure of the semiconductor device according to the first embodiment.

FIG. 4 shows an example of the structure of the cross-section of a terminal of the semiconductor device according to the first embodiment.

FIG. 5 is a perspective view showing the structure of a terminal and its associated components of the semiconductor device according to the first embodiment.

FIG. 6 is a perspective view separately showing the structures of the terminal and its associated components of the semiconductor device according to the first embodiment.

FIG. 7 shows the structure of the cross-section of the terminal of the semiconductor device according to the first embodiment.

FIG. 8 shows the structure of the cross-section of a terminal complex of the semiconductor device according to the first embodiment.

FIG. 9 is a perspective view showing a part of a manufacturing step of the terminal complex of the semiconductor device according to the first embodiment.

FIG. 10 shows the structure of the cross-section of terminals of the semiconductor device according to the first embodiment.

FIG. 11 is a perspective view showing a part of the semiconductor device according to the first embodiment.

FIG. 12 is a perspective view showing an insulator of a semiconductor device according to a modification of the first embodiment.

FIG. 13 shows the structure of the cross-section of a terminal of a semiconductor device according to a modification of the first embodiment.

FIG. 14 shows a part of a manufacturing step of a terminal complex of a semiconductor device according to a modification of the first embodiment.

### DETAILED DESCRIPTION

In general, according to one embodiment, a semiconductor device includes a first transistor, a second transistor, a first terminal, and a complex. The first and second transistors are on a substrate. A first end of the first transistor and a second end of the second transistor are coupled to each other. The first terminal includes a first portion contacting a first conductor coupled to a third end of the first transistor, a second portion connected to the first portion, and a third portion connected to the second portion. The complex includes a second terminal and a first insulator partially covering the second terminal. The second terminal includes a fourth portion, a fifth portion, and a sixth portion. The fourth portion contacts a second conductor coupled to a fourth end of the second transistor. The fifth portion is connected to the fourth portion and aligned with the second portion of the first terminal. The sixth portion is connected to the fifth portion. The first insulator covers the fifth portion.

Embodiments will now be described with reference to the figures.

The figures are schematic, and the relation between the thickness and the area of a plane of a layer and the ratio of thicknesses of layers may differ from those in actuality. The figures may include components which differ in relations and/or ratios of dimensions in different figures.

The embodiments will be described using an X-Y-Z orthogonal coordinate system. A plus direction of a vertical axis in a drawing may be referred to as an upper side, and a minus direction of the vertical axis may be referred to as a lower side. A plus direction of a horizontal axis in a drawing may be referred to as a right side, and a minus direction of the horizontal axis may be referred to as a left side. That is, in a plan view showing an X-Y plane (referred to as an X-Y plane view, the same applying hereinafter), an upper side of the X-Y plane represents a +Y direction, a lower side of the X-Y plane represents a −Y direction, a right side of the X-Y plane represents a +X direction, and a left side of the X-Y plane represents a −X direction.

### 1. First Embodiment

A semiconductor device according to the first embodiment is a power module. Examples of an application form of the semiconductor device according to the first embodiment include a power conversion device for a railroad car and an industrial device for a renewable energy power generation system.

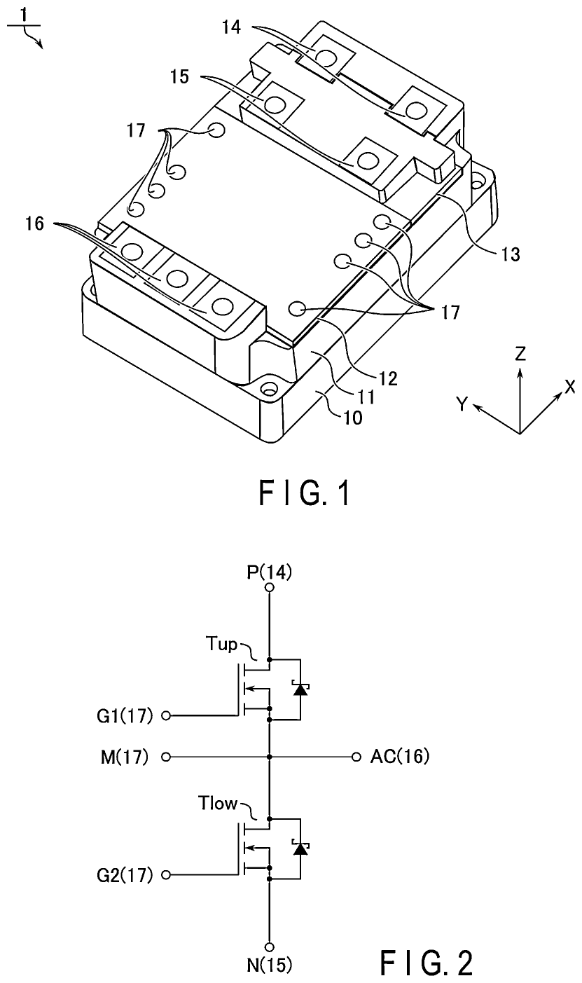

FIG. 1 is a perspective view showing an example of the outer appearance of the semiconductor device according to the first embodiment. A semiconductor device 1 includes a base substrate 10, a case 11, lids 12 and 13, one or more terminals 14, one or more terminals 15, one or more terminals 16, and one or more terminals 17. The base substrate 10, the case 11, and the lids 12 and 13 form a container of the semiconductor device 1. The internal space of the container of the semiconductor device 1 accommodates a semiconductor element and a conductor for implementing an electric circuit.

The base substrate 10 is a support body of the semiconductor device 1. The base substrate 10 has a flat plate shape, and has, for example, a quadrilateral shape. The base substrate 10 forms the lower portion of the container of the semiconductor device 1. The base substrate 10 has, for example, screw holes at four corners. The base substrate 10 contains, for example, copper (Cu) and ceramics.

The case 11 is an insulator having a tube shape. The case 11 is located on the upper surface of the base substrate 10. The case 11 forms the side portion of the container of the semiconductor device 1. The case 11 is fixed to the base substrate 10. The case 11 contains, for example, Poly-Phenylene Sulfide (PPS).

A plane on which the base substrate 10 spreads will be referred to as the X-Y plane hereinafter. The longitudinal direction of the base substrate 10 will be referred to as the X direction hereinafter, and a direction orthogonal to the X direction will be referred to as the Y direction hereinafter. A direction from the base substrate 10 to the case 11 will be referred to as the Z direction hereinafter. The Z direction is also the upper direction.

Each of the lids 12 and 13 is an insulator having a flat plate shape. The lids 12 and 13 are located on the upper surface of the case 11. The lids 12 and 13 form the upper portion of the container of the semiconductor device 1. The lids 12 and 13 are fixed to the case 11. The lids 12 and 13 each contain, for example, PPS.

Each of the terminals 14, 15, 16, and 17 is the end portion of a (not shown) conductive component that electrically couples the inside of the semiconductor device 1 and a device outside the semiconductor device 1. FIG. 1 and the following description are based on an example of two terminals 14, two terminals 15, three terminals 16, and eight terminals 17.

The terminals 14 are input terminals. The terminals 14 have P (Positive) polarity while the semiconductor device 1 operates. The terminals 14 are electrically coupled to each other. The upper surface of each of the terminals 14 is exposed from the upper surface of the lid 13. The terminals 14 are arranged in, for example, the Y direction.

The terminals 15 are input terminals. The terminals 15 have N (Negative) polarity while the semiconductor device 1 operates. The terminals 15 are electrically coupled to each other. The upper surface of each of the terminals 15 is exposed from the upper surface of the lid 13. The terminals 15 are arranged in, for example, the Y direction. The set of the terminals 15 is located in the −Y direction from the set of the terminals 14. The −Y direction faces opposite to the Y direction.

The terminals 16 are output terminals. The terminals 16 are also called AC (Alternating Current) terminals. The terminals 16 are electrically connected to each other. The upper surface of each of the terminals 16 is exposed from the upper surface of the lid 13. The set of the terminals 16 is located in the −Y direction from the set of the terminals 15.

Each of the terminals 17 is a control terminal or a monitor terminal. The control terminal is, for example, a terminal that receives a voltage for controlling the semiconductor element included in the semiconductor device 1. The monitor terminal is, for example, a terminal that outputs a voltage for monitoring the electric characteristic of the semiconductor device 1. The terminals 17 are arranged along two sides facing each other in the X direction of the lid 12.

FIG. 2 shows an example of the electric circuit of the semiconductor device according to the first embodiment. The example of FIG. 2 shows a case where the semiconductor device 1 includes transistors Tup and Tlow.

The transistors Tup and Tlow are n-type metal-oxide-semiconductor (MOS) transistors. The transistors Tup and Tlow are coupled in series.

The transistor Tup has a drain terminal coupled to a node P, a source terminal, and a gate terminal coupled to a node G1. The transistor Tlow has a drain terminal, a source terminal coupled to a node N, and a gate terminal coupled to a node G2.

The source terminal of the transistor Tup is coupled to the drain terminal of the transistor Tlow. The source terminal of the transistor Tup and the drain terminal of the transistor Tlow are coupled to nodes AC and M.

The nodes P, N, and AC correspond to the terminals 14, 15, and 16, respectively. Each of the nodes G1 and G2 corresponds to one of the terminals 17. The node M corresponds to the terminals 17.

The electric circuit implemented by the semiconductor device 1 is not limited to the example shown in FIG. 2. For example, the transistors Tup and Tlow may be insulated-gate bipolar transistors (IGBTs). A plurality of transistors Tup and/or a plurality of transistors Tlow may be provided. In this case, the plurality of transistors Tup are coupled in parallel, and the plurality of transistors Tlow are coupled in parallel.

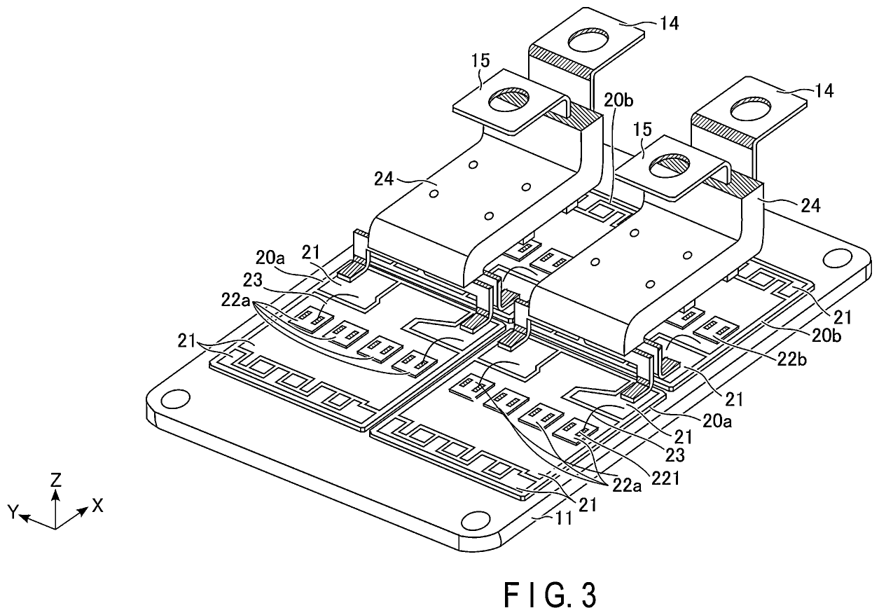

FIG. 3 schematically shows an example of the internal structure of the semiconductor device according to the first embodiment. FIG. 3 shows only the base substrate 10 and the terminals 14 and 15 among the components shown in FIG. 1. The semiconductor device 1 further includes one or more circuit substrates 20, a plurality of conductors 21, a plurality of semiconductor chips 22, a plurality of conductors 23, and a plurality of insulators 24. FIG. 3 and the following description are based on an example of four circuit substrates 20.

Each circuit substrate 20 is an insulating substrate that supports the components of the electric circuit (see FIG. 2) implemented by the semiconductor device 1. The circuit substrates 20 are located on the upper surface of the base substrate 10. The circuit substrates 20 contain, for example, silicon nitride (SIN). The circuit substrates 20 are distributed on the upper surface of the base substrate 10. In one example, the circuit substrates 20 are arranged in the X direction and the Y direction, and the following description and FIG. 3 are based on such example. The circuit substrates 20 include circuit substrates 20a located farther in the −X direction and circuit substrates 20b located farther in the X direction. One circuit substrate 20a and one circuit substrate 20b are arranged in the X direction.

The conductors 21 are interconnect patterns each having a flat plate shape. The conductors 21 are located on the upper surface of each circuit substrate 20. The conductors 21 form a part of the electric circuit of the semiconductor device 1. The shape of each conductor 21 along the X-Y plane shown in FIG. 3, which may be referred to as a planar shape hereinafter, is merely an example, and each conductor 21 may have any planar shape as long as the electric circuit shown in FIG. 2 is implemented.

The semiconductor chips 22 are chips each including a semiconductor element. The semiconductor chips 22 are located and distributed on the upper surface of one conductor 21. The semiconductor chips 22 include semiconductor chips 22a above the circuit substrates 20a and semiconductor chips 22b above the circuit substrates 20b. Each semiconductor chip 22a functions as the transistor Tlow. Each semiconductor chip 22b functions as the transistor Tup. Each semiconductor chip 22 includes terminals 221.

The conductors 23 are bonding wires. Each conductor 23 contacts one terminal 221 and one conductor 21, or contacts separate two conductors 21.

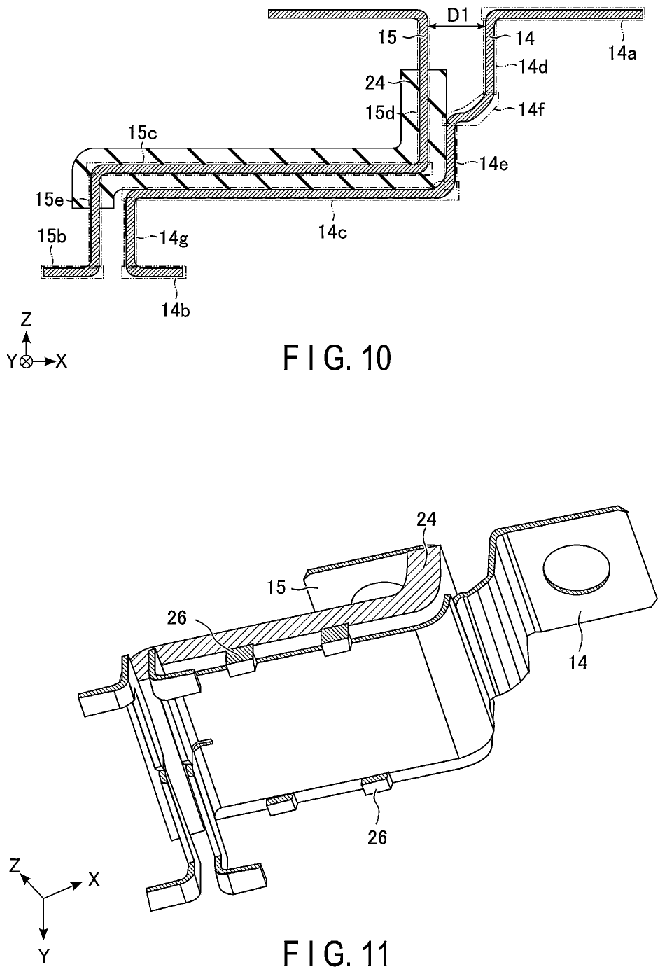

Each terminal 14 is a conductor having a flat plate shape. The terminal 14 extends while curving or bending at some points. The terminal 14 contacts at least one conductor 21 on the one circuit substrate 20b on the side opposite to the side including the surface (to be sometimes referred to as the upper surface hereinafter) exposed from the lid 13. The detailed shape of the terminal 14 will be described later with reference to FIG. 10.

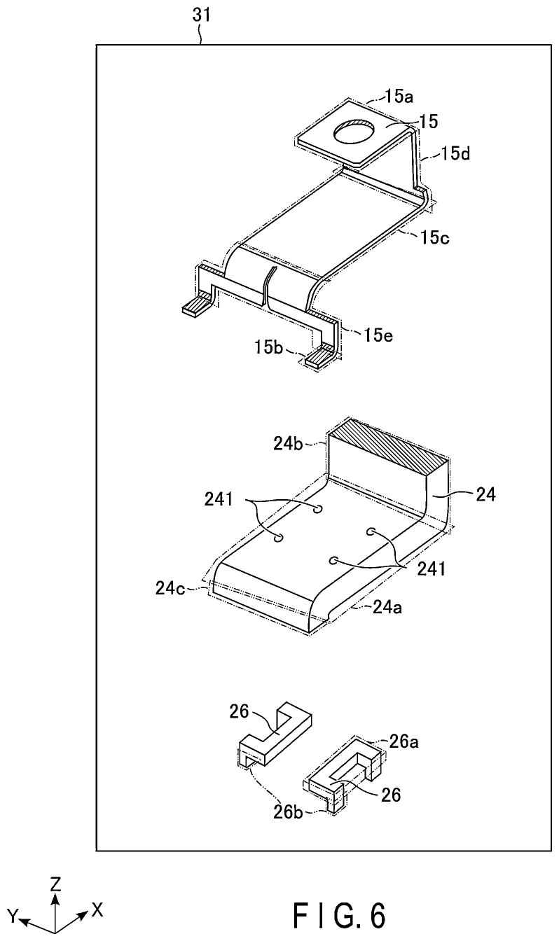

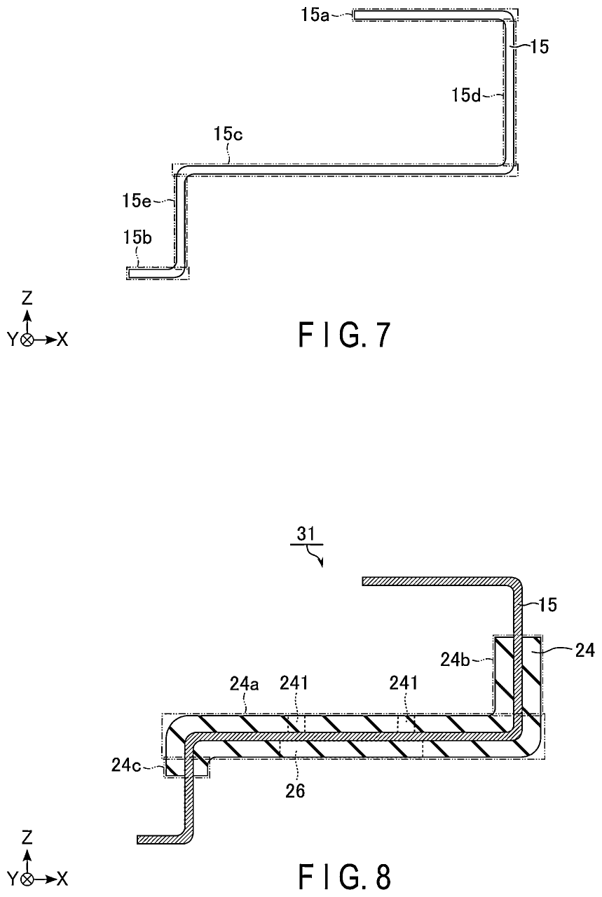

Each terminal 15 is a conductor having a flat plate shape. The terminal 15 extends while curving or bending at some points. The terminal 15 contacts at least one conductor 21 on at least one circuit substrate 20a on the side opposite to the side including the surface exposed from the lid 13, which may be referred to as the upper surface hereinafter. The detailed shape of the terminal 15 will be described later with reference to FIGS. 6 and 7.

The insulators 24 contain, for example, a resin. Each insulator 24 partially covers the terminal 15. The insulator 24 covers a portion except for the upper surface and its neighboring portion of the terminal 15, and except for a surface contacting the conductor 21 and its neighboring portion. The insulator 24 extends in conformance with the shape of the terminal 15. The detailed shape of the insulator 24 will be described later with reference to FIGS. 6 and 8.

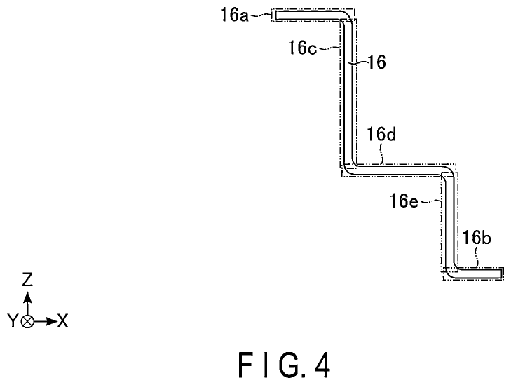

FIG. 4 shows an example of the structure of the terminal of the semiconductor device according to the first embodiment. FIG. 4 shows a state when the terminal 16 is viewed from a plane along the X-Y plane.

The terminal 16 has a flat plate shape, and has a shape obtained when a flat plate curves or bends at some points. The terminal 16 includes an upper surface portion 16a and a lower surface portion 16b. The upper surface portion 16a and the lower surface portion 16b are connected to each other via other portions.

The upper surface portion 16a occupies the top portion of the terminal 16. The upper surface portion 16a spreads along the X-Y plane. The upper surface of the upper surface portion 16a is exposed from the upper surface of the lid 13.

The lower surface portion 16b occupies the bottom portion of the terminal 16. The lower surface portion 16b spreads along the X-Y plane. The lower surface of the lower surface portion 16b contacts the upper surface of the conductor 21 corresponding to the node AC of the electric circuit (see FIG. 2) implemented by the semiconductor device 1.

The structure of a portion other than the upper surface portion 16a and the lower surface portion 16b of the terminal 16 may have any structure as long as the upper surface portion 16a and the lower surface portion 16b can be connected to each other and the lower surface portion 16b can be located above the conductor 21 to be connected to the lower surface portion 16b. An example will be described below.

In one example, the terminal 16 further includes a first intermediate portion 16c, a second intermediate portion 16d, and a third intermediate portion 16e. The first intermediate portion 16c spreads along the Y-Z plane, and is connected to one end of the upper surface portion 16a. The second intermediate portion 16d spreads along the X-Y plane, and is connected to an end of the first intermediate portion 16c opposite to the end connected to the upper surface portion 16a. The third intermediate portion 16e spreads along the Y-Z plane, and is connected to an end of the second intermediate portion 16d opposite to the end connected to the first intermediate portion 16c. In addition, the third intermediate portion 16e is connected to the lower surface portion 16b at the end opposite to the end connected to the second intermediate portion 16d. The terminal 16 generally has a shape obtained by connecting a plurality of L-shaped portions.

A plurality of upper surface portions 16a may be connected to one first intermediate portion 16c.

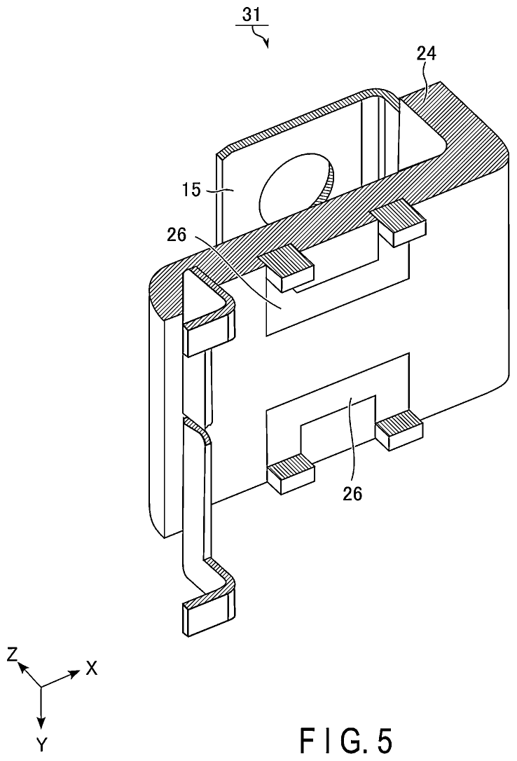

FIG. 5 is a perspective view showing the structure of the terminal and its associated components of the semiconductor device according to the first embodiment. FIG. 6 is a perspective view separately showing the structures of the terminal and its associated components of the semiconductor device according to the first embodiment. FIG. 7 shows the structure of the cross-section of the terminal of the semiconductor device according to the first embodiment. FIG. 8 shows the structure of the cross-section of a terminal complex of the semiconductor device according to the first embodiment.

As shown in FIG. 5, the terminal 15 is partially located in the insulator 24, and partially covered with the insulator 24. The terminal 15 and the insulator 24 are integrated. A structure including the set of the terminal 15 and the insulator 24 may be referred to as a terminal complex 31 hereinafter. The terminal complex 31 can be formed by insert molding.

The terminal complex 31 can further include a plurality of insulators 26. The insulator 24 includes the insulators 26 in a portion including the lower surface. The insulators 26 are made of, for example, a resin. The insulators 26 are fixed to the insulator 24 by the insert molding for forming the terminal complex 31.

As shown in FIGS. 6 and 7, the terminal 15 includes an upper surface portion 15a, at least one lower surface portion 15b, and a first intermediate portion 15c. FIGS. 5 and 7 and the following description are based on an example of two lower surface portions 15b.

The upper surface portion 15a occupies the top portion of the terminal 15. The upper surface portion 15a spreads along the X-Y plane. The upper surface of the upper surface portion 15a is exposed from the upper surface of the lid 13.

The lower surface portion 15b occupies the bottom portion of the terminal 15. The lower surface portion 15b spreads along the X-Y plane. The lower surface of the lower surface portion 15b contacts the upper surface of the conductor 21 corresponding to the node N of the electric circuit (see FIG. 2) implemented by the semiconductor device 1.

The first intermediate portion 15c spreads along the X-Y plane. In one example, the first intermediate portion 15c extends in the X direction. The first intermediate portion 15c is connected to the upper surface portion 15a and the lower surface portion 15b via other portions of the terminal 15 at opposite sides, respectively. The first intermediate portion 15c is partially located in a region immediately below the upper surface portion 15a, and partially faces the upper surface portion 15a. In one example, the first intermediate portion 15c is not located in a region immediately above the lower surface portion 15b, and does not face the lower surface portion 15b.

The structure of a portion other than the upper surface portion 15a, the lower surface portion 15b, and the first intermediate portion 15c of the terminal 15 may have any structure as long as the first intermediate portion 15c can be connected to the upper surface portion 15a and the lower surface portion 15b and the lower surface portion 15b can be located above the conductor 21 to be connected to the lower surface portion 15b. An example will be described below.

In one example, the terminal 15 further includes a second intermediate portion 15d and a third intermediate portion 15e. The second intermediate portion 15d spreads along the Y-Z plane, and is connected to, at two opposite sides, one side of the upper surface portion 15a and one side of the first intermediate portion 15c, respectively.

The third intermediate portion 15e spreads along the Y-Z plane, and is connected to the lower surface portion 15b at the side opposite to the side of the first intermediate portion 15c connected to the second intermediate portion 15d. In an example, the third intermediate portion 15e branches into two parts on the side of the lower surface portion 15b. Each of the two parts has a shape obtained by connecting a plurality of L-shaped portions along the Y-Z plane.

As shown in FIGS. 6 and 8, the insulator 24 partially surrounds the terminal 15, and does not surround at least the upper surface portion 15a and the lower surface portion 15b of the terminal 15. The insulator 24 has, in the portion surrounding the terminal 15, a shape conforming to the shape of the portion of the terminal 15 surrounded by the insulator 24. A detailed description will be provided below.

The insulator 24 includes a first portion 24a, a second portion 24b, and a third portion 24c. The first portion 24a occupies the intermediate portion of the insulator 24. The first portion 24a spreads along the X-Y plane and extends in the X direction. The first portion 24a surrounds the first intermediate portion 15c of the terminal 15, contains the first intermediate portion 15c, and contacts the first intermediate portion 15c. The first portion 24a includes a plurality of holes (openings) 241. Each hole 241 extends from the upper surface of the first portion 24a to the upper surface of the terminal 15. The first portion 24a includes a portion having a shape conforming to the outer shape of the insulator 26.

The second portion 24b occupies the top portion of the insulator 24. The second portion 24b spreads along the Y-Z plane. The second portion 24b is connected to the first portion 24a at the lower end. The second portion 24b surrounds a part of the second intermediate portion 15d of the terminal 15, surrounds the lower portion of the second intermediate portion 15d, and contains the lower portion of the second intermediate portion 15d. The second portion 24b contacts the second intermediate portion 15d of the terminal 15. The position of the upper end (upper surface) of the second portion 24b at least partially depends on the shape of the terminal 14. The position of the upper end of the second portion 24b will be described later with reference to FIG. 10.

The third portion 24c occupies the bottom portion of the insulator 24. The third portion 24c spreads along the Y-Z plane. The upper end of the third portion 24c is connected to the end of the first portion 24a facing the end connected to the second portion 24b. The third portion 24c surrounds a part of the third intermediate portion 15e of the terminal 15, surrounds the upper portion of the third intermediate portion 15e, and contains the upper portion of the third intermediate portion 15e. The third portion 24c contacts the third intermediate portion 15e of the terminal 15.

The insulator 24 generally has a shape obtained by connecting a plurality of L-shaped portions along the X-Z plane.

As shown in FIGS. 5 and 6, the insulator 26 includes a first portion 26a and projecting portions 26b. The first portion 26a has a shape obtained when a rectangular parallelepiped extending in the X direction is removed from another rectangular parallelepiped extending in the X direction, and has such columnar shape that a U shape bending along the X-Y plane extends in the Z direction. The projecting portion 26b is connected to the first portion 26a, and has a rectangular parallelepiped shape extending in the Z direction. The first portion 26a is located in the insulator 24 and has, for example, a lower surface (the X-Y plane located farthest in the −Z direction) aligned with the lower surface (the X-Y plane located farthest in the −Z direction) of the insulator 24. The projecting portion 26b partially projects from the lower surface of the insulator 24.

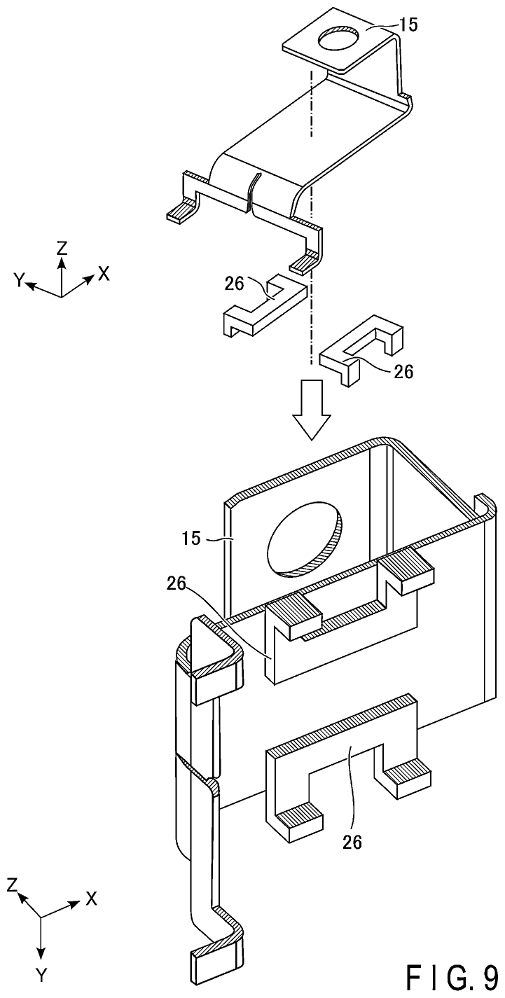

FIG. 9 is a perspective view showing a part of a manufacturing step of the terminal complex of the semiconductor device according to the first embodiment. The terminal complex 31 is formed by insert molding using a device for forming the insulator 24. The device contains a mold surrounding a space along the shape of the insulator 24.

As shown in FIG. 9, the insulator 26 is placed in the mold in a state in which the projecting portions 26b face in the −Z direction. The mold includes holes and the projecting portions 26b are inserted into the holes. The terminal 15 is arranged, in such direction that the first intermediate portion 15c is along the X-Y plane, on the upper surface of the insulator 24 in the internal space of the mold. FIG. 9 shows a state in which the terminal 15 and the insulator 26 are arranged in the mold in the lower portion. The terminal 15 is fixed by receiving pressure by rods on the side in the Z direction. In this state in which the terminal 15 and the insulator 26 are thus arranged, the material of the insulator 24 is injected into the internal space of the mold. While the material of the insulator 24 is injected and formed, the projecting portions 26b fix the position of the terminal 15 to suppress the terminal 15 from moving and (or) rotating. By insert molding by injecting the material of the insulator 24, the terminal complex 31 is formed, as shown in FIG. 5. The holes 241 of the insulator 24 are formed by not forming the insulator 24 in regions where the rods for fixing the terminal 15 are located during insert molding.

FIG. 10 shows the structure of the cross-section of the terminals of the semiconductor device according to the first embodiment. FIG. 10 shows the terminal complex 31 (the set of the terminal 15 and the insulator 24) and also shows the arrangement of the terminal complex 31 and the insulator 24 in the semiconductor device 1.

As shown in FIG. 10, the terminal 14 includes an upper surface portion 14a, at least one lower surface portion 14b, a first intermediate portion 14c, and a second intermediate portion 14d. The terminal 14 has a shape partially conforming to the outer shape of the terminal complex 31, more specifically, the insulator 24 of the terminal complex 31. The upper surface of the terminal 14 partially contacts or is close to the lower surface of the insulator 24.

The upper surface portion 14a occupies the top portion of the terminal 14. The upper surface portion 14a spreads along the X-Y plane. The upper surface of the upper surface portion 14a is exposed from the upper surface of the lid 13.

The lower surface portion 14b occupies the bottom portion of the terminal 14. The lower surface portion 14b spreads along the X-Y plane. The lower surface of the lower surface portion 14b contacts the upper surface of the conductor 21 corresponding to the node P of the electric circuit (see FIG. 2) implemented by the semiconductor device 1.

The first intermediate portion 14c spreads along the X-Y plane. The first intermediate portion 14c is connected to the lower surface portion 14b via another portion of the terminal 14. The first intermediate portion 14c is located in a region immediately above the lower surface portion 14b, and faces the lower surface portion 14b. The first intermediate portion 14c faces the first intermediate portion 15c of the terminal 15. The first intermediate portion 14c is not located in a region immediately below the upper surface portion 14a, and does not face the upper surface portion 14−a.

The second intermediate portion 14d spreads along the Y-Z plane. The second intermediate portion 14d is connected to an end of the upper surface portion 14a via another portion of the terminal 14. The second intermediate portion 14d faces the second intermediate portion 15d of the terminal 15. The second intermediate portion 14d has a distance D1 from the second intermediate portion 15d of the terminal 15. The distance D1 is larger than the distance between the first intermediate portion 14c and the first intermediate portion 15c of the terminal 15. The second intermediate portion 14d faces the insulator 24. In one example, the position of the upper end of the insulator 24 in the Z direction is located on the lower side of the upper end of the second intermediate portion 14d and on the upper side of the lower end of the second intermediate portion 14d.

The structure of a portion other than the upper surface portion 14a, the lower surface portion 14b, the first intermediate portion 14c, and the second intermediate portion 14d of the terminal 14 may have any structure as long as the first intermediate portion 14c can be connected to the lower surface portion 14b and the second intermediate portion 14d and the lower surface portion 14b can be located above the conductor 21 to be connected to the lower surface portion 14b. An example will be described below.

In one example, the terminal 14 further includes a third intermediate portion 14e, a fourth intermediate portion 14f, and a fifth intermediate portion 14g. The third intermediate portion 14e spreads along the Y-Z plane, and is connected to an end of the first intermediate portion 14c. The third intermediate portion 14e faces the second intermediate portion 15d of the terminal 15. The distance between the third intermediate portion 14e and the second intermediate portion 15d of the terminal 15 is smaller than the distance D1.

The fourth intermediate portion 14f is connected to an end of the second intermediate portion 14d and an end of the third intermediate portion 14e. The shape of the fourth intermediate portion 14f along the X-Y plane is curved. The upper end of the fourth intermediate portion 14f, that is, the end connected to the second intermediate portion 14d is located on the lower side (the side in the −Z direction) of the upper end of the insulator 24.

The fifth intermediate portion 14g spreads along the Y-Z plane. The fifth intermediate portion 14g is connected to an end of the first intermediate portion 14c and an end of the lower surface portion 14b. In one example, as shown in FIG. 11 to be described later, the fifth intermediate portion 14g branches into two parts on the side of the lower surface portion 14b. Each of the two parts has a shape obtained by connecting a plurality of L-shaped portions along the Y-Z plane. In this example, each of the two parts of the fifth intermediate portion 14g has the same shape as that of each of the two parts of the third intermediate portion 15e of the terminal 15, and they face each other.

FIG. 11 is a perspective view showing a part of the semiconductor device according to the first embodiment. FIG. 11 also shows the positional relationship between the terminal complex 31 (the set of the terminal 15 and the insulators 24 and 26) and the terminal 14 in the semiconductor device 1. As shown in FIG. 11 and described with reference to FIG. 10, the terminal 14 contacts the terminal complex 31, more specifically, the insulator 24. The terminal 14 is arranged so that the first intermediate portion 14c of the terminal 14 is located in a region between the projecting portions 26b of the insulator 26. That is, when the terminal complex 31 is arranged on the terminal 14, the projecting portions 26b of the insulator 26 can function as guides of alignment between the terminal complex 31 and the terminal 14.

According to the semiconductor device of the first embodiment it is possible to provide a semiconductor device that can be manufactured by a simplified step while suppressing inductance as described below.

The structure for implementing the electric circuit shown in FIG. 2 includes two terminals having portions facing each other at a short distance like the terminals 14 and 15, thereby making it possible to suppress inductance. That is, when one of the transistors Tup and Tlow that are OFF is turned on, a current flows between the terminals 14 and 15. In general, if the state of a current flowing through a conductor changes, inductance is generated in the conductor and functions as a resistance to the current. While the current flows between the terminals 14 and 15, the direction (in FIG. 9, the −X direction) of the current flowing through the terminal 14 is opposite to the direction (in FIG. 9, the X direction) of the current flowing through the terminal 15. Therefore, the inductance generated by the current flowing through the terminal 14 and the inductance generated by the current flowing through the terminal 15 have opposite polarities. Thus, by arranging the terminals 14 and 15 at a short distance, the inductance generated by the current flowing through the terminal 14 and the inductance generated by the current flowing through the terminal 15 are mutually canceled. In the semiconductor device 1, the inductance is thus suppressed.

To suppress inductance, the distance between the terminals 14 and 15 is preferably small. On the other hand, it is necessary to secure insulation between the terminals 14 and 15. For this purpose, it is considered to arrange an insulator between the terminals 14 and 15. However, in this case, in the manufacturing step of the semiconductor device 1, the terminals 14 and 15 and the insulator need to be separately arranged. This manufacturing step makes it difficult to align the terminals 14 and 15 and the insulator.

To facilitate alignment, it is considered to form the terminal 15 and the insulator that covers the terminal 15 by insert molding. In general, the pressure of a resin supplied to the internal space of the mold during insert molding is high. Thus, it is necessary to fix the position of the terminal 15. For this purpose, it is considered to sandwich the terminal 15 by a rod contacting the upper surface of the terminal 15 and a rod contacting the lower surface of the terminal 15. In this case, with the same mechanism as that described with reference to FIG. 8, in addition to the holes 241, a hole reaching the terminal 15 from the lower surface is formed in the first portion 24a of the insulator 24. With this hole, the terminals 14 and 15 face each other via air in the internal portion of the hole. Since the distance between the terminals 14 and 15 is small, insulation between the terminals 14 and 15 cannot be secured in the portion of the hole due to the presence of the hole.

According to the first embodiment, the insulator 24 and the terminal 15 are formed by insert molding. Thus, the insulator 24 and the terminal 15 have an integrated structure as the terminal complex 31. Therefore, it is easy to arrange the terminal 15 (terminal complex 31) and the terminal 14.

The semiconductor device 1 according to the first embodiment includes the insulators 26. The insulators 26 fix the terminal 14 while being formed by insert molding of the insulator 24. Thus, a structure (for example, a rod) that is located in the −Z direction of the terminal 15 and fixes the terminal 15 during insert molding is unnecessary. It is possible to suppress absence of the insulator 24 in a region where the structure is located, and in turn formation of the space in the insulator 24 located in the −Z direction from the terminal 15. Therefore, it is possible to secure insulation between the terminals 14 and 15.

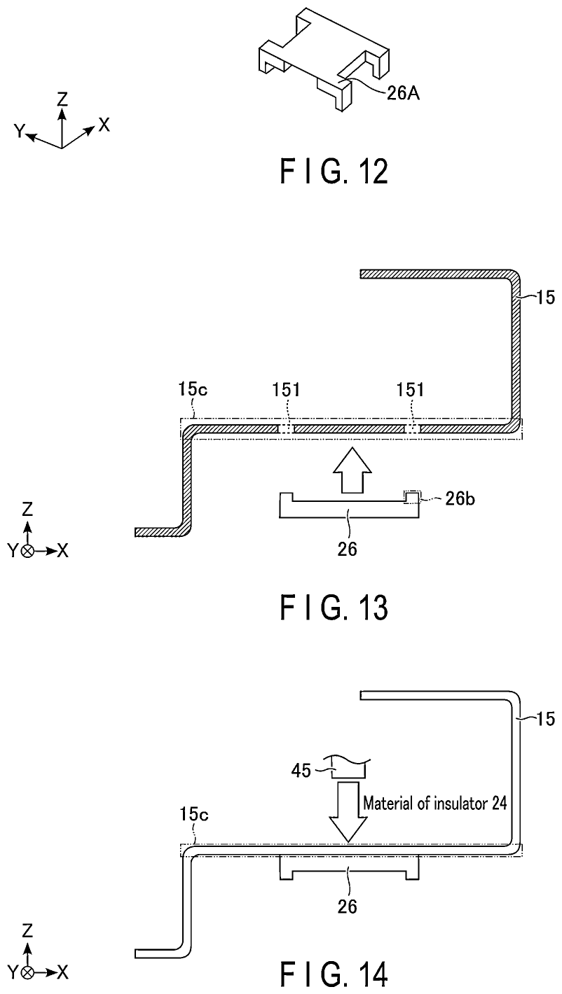

Instead of providing the two insulators 26, one insulator 26A may be provided, as shown in FIG. 12. In this case, the insulator 26A has a structure obtained by connecting the two insulators 26 shown in FIGS. 5 and 6.

As shown in FIG. 13, the insulator 26 may include the projecting portions 26b in the Z direction. In this case, the terminal 15 includes holes (openings) 151 in the first intermediate portion 15c. The hole 151 extends from the upper surface of the first intermediate portion 15c to its lower surface. The projecting portions 26b are located in the holes 151. The projecting portions 26b are inserted into the holes 151 during insert molding. Even if the holes 151 exist, regions immediately below the holes 151 are occupied by the insulator 26. Therefore, even if the holes 151 exist, insulation between the terminals 14 and 15 is secured.

As shown in FIG. 14, the rods that fix the terminal 15 need not be used during insert molding. In this case, an outlet 45 that emits the material of the insulator 24 is located above the first intermediate portion 15c of the terminal 15 and the insulator 26. The emitted material of the insulator 24 applies pressure to the first intermediate portion 15c, thereby fixing the position of the terminal 15. In this case, the insulator 24 includes no holes 241.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor and a second transistor on a substrate wherein a first end of the first transistor and a second end of the second transistor are coupled to each other;
a first terminal including a first portion contacting a first conductor coupled to a third end of the first transistor, a second portion connected to the first portion, and a third portion connected to the second portion; and
a complex including a second terminal and a first insulator partially covering the second terminal wherein the second terminal includes a fourth portion, a fifth portion, and a sixth portion, the fourth portion contacts a second conductor coupled to a fourth end of the second transistor, the fifth portion is connected to the fourth portion and aligned with the second portion of the first terminal, the sixth portion is connected to the fifth portion, and the first insulator covers the fifth portion.

2. The device according to claim 1, wherein
the fourth portion includes a first sub-portion including a region connected to the fifth portion,
the sixth portion includes a second sub-portion including a region connected to the fifth portion, and
the first insulator further covers the first sub-portion and the second sub-portion.

3. The device according to claim 2, wherein
the first insulator is continuous over a region around the fifth portion, a region around the first sub-portion, and a region around the second sub-portion.

4. The device according to claim 3, wherein
the fifth portion is located in a first direction from the second portion,
the first insulator covers a surface of the fifth portion facing to the first direction and a surface of the fifth portion facing to a second direction, and
the second direction faces opposite to the first direction.

5. The device according to claim 4, wherein
the fourth portion is located in a third direction from the first portion,
the sixth portion is located in the third direction from the third portion,
the first insulator covers a surface of the fourth portion facing to the third direction, a surface of the fourth portion facing to a fourth direction, a surface of the sixth portion facing to the third direction, and a surface of the sixth portion facing to the fourth direction, and
the fourth direction faces opposite to the third direction.

6. The device according to claim 1, wherein
the complex further includes a second insulator, and
the first insulator includes the second insulator in a portion covering the fifth portion.

7. The device according to claim 6, wherein
the second insulator includes
a seventh portion, and
at least one eighth portion connected to the seventh portion and projecting from the first insulator.

8. The device according to claim 6, wherein
the fifth portion includes an opening, and
the second insulator includes
a seventh portion, and
at least one eighth portion connected to the seventh portion and located in the opening.

9. The device according to claim 1, wherein
the first insulator and the second terminal are integrated.

10. The device according to claim 1, wherein
the first insulator and the second terminal are formed by insert molding.
